(19) United States
(12) Patent Application Publication
(10) Pub. No.: US 2006/0151774 A1
(43) Pub. Date: Jul. 13, 2006

(54) Field emitter array and method for manufacturing the same

(75) Inventors: Sang Moon Lee, Seoul (KR); Hyoung Dong Kang, Suwon (KR); Ji Woon Lee, Gwangju (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/267,285

(22) Filed: Nov. 7, 2005

(30) Foreign Application Priority Data
Jan. 7, 2005 (KR) 10-2005-1834

(51) Int. Cl. H01L 29/06; H01L 21/00

(52) U.S. Cl. 257/10; 438/20; 313/326

(57) ABSTRACT

A field emitter array, and a method for manufacturing the same are provided. The field emitter array comprises a nickel substrate, and a plurality of nano-pillars extending perpendicular to the nickel substrate. Each of the nano-pillars comprises a nickel nano-pillar body integrated to the nickel substrate and extending perpendicular to the nickel substrate, and an upper portion of the nano-pillar comprising a CNT-nickel composite material. At least one CNT is exposed from an upper surface of the upper portion of the nano-pillar. Since the CNTs are provided on the upper surface of the nano-pillars, field emission efficiency can be further enhanced. Additionally, since the substrate, and the nano-pillars extending perpendicular to the substrate are integrated and formed of the same material, contact resistance between the substrate and the nano-pillars is reduced, thereby enhancing the field emission efficiency.

### RELATED APPLICATION

The present invention is based on, and claims priority from, Korean Application Number 2005-1834, filed Jan. 7, 2005, the disclosure of which is incorporated by reference herein in its entirety.

### BACKGROUND OF THE INVENTION

1. Field of the Invention

The present invention generally relates to a field emitter array, and a method for manufacturing the same. More particularly, the present invention relates to a method of manufacturing a field emitter array using a porous anodized alumina layer and a field emitter array manufactured thereby.

2. Description of the Related Art

Generally, a field emission display (FED) comprises a field emitter array formed with a plurality of fine tips or emitters which are induced to emit electrons by a strong electric field. The electrons emitted from the emitters are accelerated into a phosphor screen in a vacuum, and excite phosphors on the screen to emit light. Unlike a CRT display, the field emission display neither requires electron beam steering circuitry, nor produces large amount of unwanted heat. Additionally, unlike a LCD display, the field emission displays requires no back light, illuminates very brightly, and has a very wide viewing angle and a very short response time. Performance of the field emission display is mainly dependant upon the field emitter array which emits electrons. Recently, in order to enhance field emission properties, carbon nano-tubes (hereinafter, also referred to as “CNTs”) are utilized as the emitters.

Conventionally, CNT emitter arrays are manufactured by a screen printing method wherein a field emission material is formed by mixing the CNTs, a binder, glass powders and silver, and is then printed on a substrate. However, the screen printing method has problems in that the binder causes an out-gassing phenomenon, and in that the CNTs are deteriorated during a heat treatment process. Moreover, according to this method, field emission efficiency is lowered due to non-uniform distribution of the CNTs, and life span of the field emission display is relatively short due to lower attachment strength of the emitters.

As for another method for manufacturing the CNT-adopting emitter array, a method of growing the CNTs on a substrate through chemical vapor deposition (CVD) has been suggested. FIGS. 1a to 1d are step diagrams illustrating a conventional method for manufacturing the CNT-adopting emitter array by means of CVD. First, referring to FIG. 1a, after depositing a metallic layer 13 on a substrate 11, a dielectric layer 15 consisting of SiO₂ and the like, and a photoresist layer 17 are sequentially formed thereon. Then, as shown in FIG. 1b, after forming a photoresist layer pattern 17a by patterning the photoresist layer 17, a dielectric layer pattern 15a is formed by selectively etching the dielectric layer 15 using the photoresist layer pattern 17a as a mask. Then, as shown in FIG. 1c, a metal catalyst seed layer 19 consisting of cobalt and the like is deposited on the metallic layer 13 by a sputtering process using the dielectric layer pattern 15a as a deposition mask. Next, as shown in FIG. 1d, CNTs 20 are formed on the metal catalyst seed layer 19 by the CVD process. As a result, a field emitter array having emitters formed of the CNTs 20 is manufactured.

However, the conventional CVD process described above is difficult to apply to a large size field emitter array, and provides non-uniform distribution of the CNT emitters. Moreover, in the conventional CVD process, it is difficult to control the distribution density of the CNT emitters while providing enhanced attachment strength of the CNT emitters, and productivity is poor.

### SUMMARY OF THE INVENTION

The present invention has been made to solve the above problems, and it is an object of the present invention to provide a method for manufacturing a field emitter array, which can enhance field emission efficiency and easily control a distribution density of CNT emitters while realizing high uniformity and attachment strength of the CNT emitters, and a field emitter array manufactured thereby.

In accordance with one aspect of the present invention, the above and other objects can be accomplished by the provision of a field emitter array, comprising: a nickel substrate; and a plurality of nano-pillars extending perpendicular to the nickel substrate. Each of the nano-pillars comprises a nickel nano-pillar body integrated to the nickel substrate and extending perpendicular to the nickel substrate, and an upper portion of the nano-pillar formed on the nano-pillar body and comprising a CNT-nickel composite material. At least one CNT may be exposed from an upper surface of the nano-pillars. The exposed CNT may act as an emitter. The CNT may be exposed only form an upper surface of the upper portion of the nano-pillar.

Each of the nano-pillars may comprise an upper portion of the nano-pillar, and a nano-pillar body. The nano-pillar body may comprise nickel, and be integrally formed to the nickel substrate. Accordingly, there is no problem of contact resistance between the nano-pillar and the nickel substrate.

Each of the nano-pillars may have a length of 2˜5 μm, and a diameter of 100˜400 nm. Additionally, the upper portion of the nano-pillar may comprise a CNT-nickel composite material, and have a length of 0.1˜0.2 μm. The nickel substrate may have a thickness of 50˜100 μm.

In accordance with another aspect of the invention, a method for manufacturing a field emitter array, comprising the steps of: preparing an aluminum substrate having an anodized alumina layer formed thereon, the anodized alumina layer having a plurality of pores uniformly distributed thereon; performing CNT-nickel composite plating using a nickel plating solution having CNTs dispersed therein, such that the CNT-nickel composite material is embedded a predetermined depth into the pores; forming a nickel layer so as to completely fill the pores and to have a predetermined thickness on the anodized alumina layer; and forming a plurality of nano-pillars, each having at least one CNT exposed from an upper surface thereof, by removing the aluminum substrate and the anodized alumina layer. The exposed CNT may act as an emitter of a field emitter device.

The CNT-dispersed nickel plating solution may comprise a cationic dispersing agent. The cationic dispersing agent may be at least one selected from the group consisting of benzene konium chloride (BKC), sodium dodecylbenzene sulfonate (NaDDBS), and triton-X. The cationic dispersing agent having a phenyl group acts to prevent the CNTs from being agglomerated in the plating solution. The content of the dispersing agent in the nickel plating solution may be about 100˜200 wt % of the amount of the CNTs.

The step of forming the nickel layer so as to completely fill the pores may be performed by electroplating. Since the nickel layer and the CNT-nickel composite material are both composed of nickel, contact resistance between the nickel layer and the CNT-nickel composite material can be reduced, thereby enhancing field emission efficiency.

The step of forming the plurality of nano-pillars may comprise: wet etching the aluminum substrate; and wet etching the anodized alumina layer. When wet etching the aluminum substrate, the at least one CNT must be protruded by etching a portion of a metallic material in the CNT-nickel composite material. Wet etching of the aluminum substrate may be performed using a nitric acid solution. Wet etching of the anodized alumina layer may also be performed using a phosphoric acid solution. A portion of nickel in the CNT-nickel composite material may be removed from the CNT-nickel composite material when wet etching the aluminum substrate using the nitric acid solution. Accordingly, some CNTs in the CNT-nickel composite material are exposed to the outside.

Each of the nano-pillars formed by wet etching may comprise an upper portion of the nano-pillar comprising the CNT-nickel composite material, and a nano-pillar body comprising a portion of the metal layer. Since the CNTs are provided to the upper portion of the nano-pillar, there is no problem of field emission at a side or a lower surface of the nano-pillars. Thus, the field emission efficiency can be further enhanced.

Each of the pores may have a total depth of 2˜5 μm, and a diameter of 100˜400 nm. The CNT-nickel composite material may be formed to a length of about 0.1˜0.2 μm in each of the pores. The nickel layer may have a thickness of 50˜100 μm on the anodized alumina layer. The nickel layer acts as a substrate for the field emitter array. Thus, the nickel layer is preferably formed to a sufficient thickness so as to stably support the nano-pillars.

The present invention can realize uniform distribution and high attachment strength of the CNT emitters while enhancing the field emission efficiency. For this purpose, according to the invention, the nano-pillars comprising the upper portions of the CNT-nickel composite material and the nano-pillar bodies of nickel are formed using the anodized porous alumina layer. The CNTs are exposed from the upper surface of the nano-pillars. As such, the exposed CNTs act as the emitters of the field emission display. With the method of the invention, the distribution density of the CNT emitters can be easily controlled by controlling the density of the pores in the anodized alumina layer.

### BRIEF DESCRIPTION OF THE DRAWINGS

The above and other objects, features and other advantages of the present invention will be more clearly understood from the following detailed description taken in conjunction with the accompanying drawing:

FIGS. 1a to 1d are step diagrams of a conventional method for manufacturing a field emitter array;

FIG. 2 is a cross-sectional view of a field emitter array according to one embodiment of the present invention;

FIGS. 3 to 8 are diagrams illustrating a method for manufacturing a field emitter array according to one embodiment of the present invention; and

FIG. 9 is a schematic view illustrating carbon nano-tubes coupled to a cationic dispersing agent.

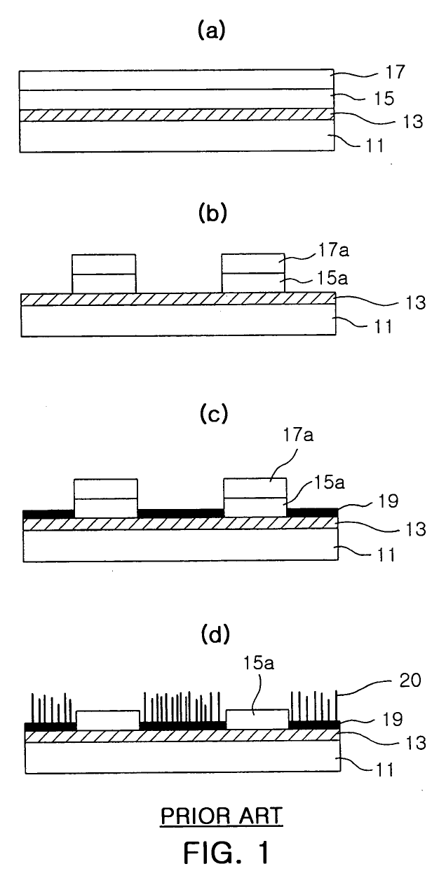

### DESCRIPTION OF THE PREFERRED EMBODIMENTS

Preferred embodiments will now be described in detail with reference to the accompanying drawings. It should be noted that the embodiments of the invention can be modified in various shapes, and that the present invention is not limited to the embodiments described herein. The embodiments of the invention are described so as to enable those having an ordinary knowledge in the art to have a perfect understanding of the invention. Accordingly, shape and size of components of the invention are enlarged in the drawings for clear description of the invention. Like components are indicated by the same reference numerals throughout the drawings.

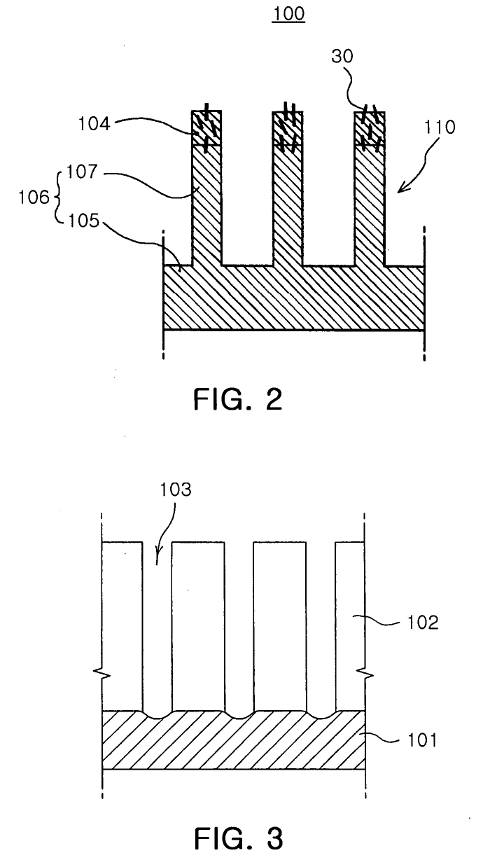

FIG. 2 is a cross-sectional view of a field emitter array 100 according to one embodiment of the invention. Referring to FIG. 2, a plurality of nano-pillars 110 extends perpendicular to a nickel substrate 105. Each of the nano-pillars 110 comprises a nano-pillar body 107 integrally formed to the substrate 105 while extending perpendicular thereto, and an upper portion 104 formed on the nano-pillar body 107. As with the substrate 105, the nano-pillar body 107 comprises nickel. However, the upper portion 104 of the nano-pillar comprises a CNT-nickel composite material. The CNT-nickel composite material of the upper portion 104 is composed of nickel, and CNTs embedded in nickel. The CNT-nickel composite may be formed by CNT-nickel composite plating as described below. Here, the term “CNT-nickel composite plating” means plating using a nickel plating solution containing the CNTs dispersed therein.

As shown in FIG. 2, at least one CNT is exposed from an upper surface of the upper portion 104 composed of the CNT-nickel composite material. In this manner, the CNT is protruded from the upper surface of the upper portion 104 (preferably, in the perpendicular direction), and acts as an emitter, which can emit electrons upon operation of the field emitter array. In particular, as shown in FIG. 2, the at least one CNT is protruded only from the upper surface of each upper poriton 104 of the nano-pillar. According to the present embodiment, since the CNTs are protruded only from the upper surface of the nano-pillars 110, there is no possibility of field emission from a side surface or a lower surface of the nano-pillars 110.

If the CNTs are protruded from the side surface or the lower surface of the nano-pillars 110, field emission occurs from the side surface or the lower surface of the nano-pillars 110. As such, when the field emission occurs from the side surface or the lower surface of the nano-pillars 110 overall field emission efficiency is lowered due to interference between field emissions from the side surfaces and lower surfaces of adjacent nano-pillars 110. Thus, it is desirable that field emission from both the side surface and from the lower surface of the nano-pillars 110 is prevented. In the present invention, since the CNTs are protruded only from the upper surface of the nano-pillars 110, the field emission efficiency can be further enhanced.

Moreover, the nano-pillar body 107 and the substrate 105 are formed of nickel, and are integrated to constitute a nickel layer 106. As such, since the nano-pillar body 107 and the substrate 105 are formed of the same material, nickel, there is no problem of contact resistance between the nano-pillars and the substrate. Thus, unlike the prior technology, the invention can prevent the field emission efficiency from being lowered due to the contact resistance between the nano-pillars and the substrate. Additionally, since the CNTs 30 acting as the field emitters are embedded in nickel, attachment strength of CNT emitters, and life span of the field emitter array can be remarkably enhanced.

A method for manufacturing a field emitter array according to the invention will now be described with reference to FIGS. 3 to 8. Herein, anodized alumina is also referred to as anodized aluminum oxide (AAO).

First, referring to FIG. 3, an aluminum substrate 101 having a porous anodized alumina layer 102 formed thereon is prepared. The porous AAO layer 102 has a plurality of pores 103 uniformly distributed thereon. The porous AAO layer 102 can be formed by an aluminum oxide anodizing process which is known in the art.

More specifically, the porous AAO layer 102 is formed by the following processes. First, an aluminum substrate is cleaned and degreased by electro-polishing. Electro-polishing can be performed by applying electric current to the aluminum substrate dipped into electrolyte consisting of, for example, a mixture of sulfuric acid, phosphorous acid and deionized water. Then, the electro-polished aluminum substrate is dipped into a phosphoric acid solution, and the anodizing process is then performed by applying a predetermined voltage to the aluminum substrate. At this time, a carbon electrode is provided as a negative electrode and the aluminum substrate is provided as a positive electrode. As a result, the porous AAO layer 102 comprising the uniformly distributed pores 103 is formed on the aluminum substrate. At this time, the depth and density of the pores 103 can be controlled by adjusting time and voltage for the anodizing process. After the anodizing process, the diameter of the pores can be increased by dipping and etching the AAO layer into the phosphoric acid solution, if necessary.

According to the present embodiment, the pores are formed to a depth of about 2˜5 μm, and a diameter of about 100˜400 nm. If the pores are formed to an excessive depth or a significantly smaller diameter, it is difficult to fill the pores with the CNT-nickel composite material in a subsequent process. Meanwhile, if the pores are formed to a significantly smaller depth or a significantly larger diameter, the nano-pillars are formed to a significantly shorter length or an excessive width by the subsequent process, thereby reducing field emission efficiency.

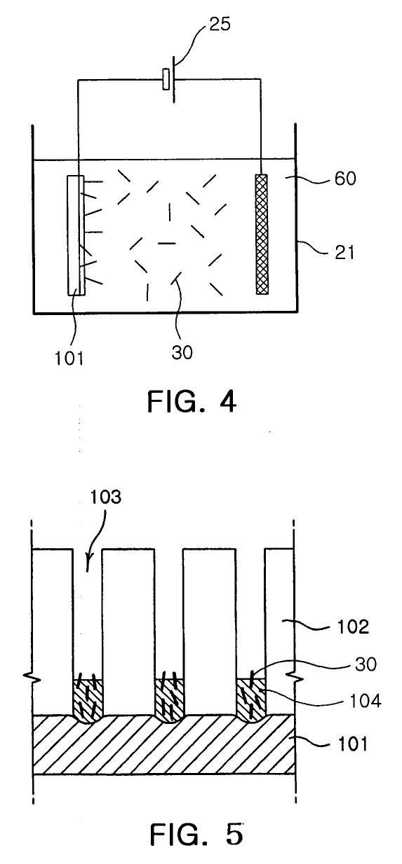

Then, as shown in FIG. 4, electro-plating (CNT-nickel composite plating) is performed on the aluminum substrate 101 formed with the AAO layer 102 by use of a nickel plating solution 60 having the CNTs 30 dispersed therein. With CNT-nickel composite plating, the CNT-nickel composite material is embedded a predetermined depth into the pores 103.

More specifically, first, the nickel plating solution 60 having the CNTs dispersed therein is prepared. The nickel plating solution 60 comprises the CNTs, nickel ions, and cationic dispersing agent. Then nickel ions are supplied mainly from NiSO₄ and NiCl₂. In order to uniformly distribute the CNTs in the plating solution 60, the plating solution 60 comprises the cationic dispersing agent. As for the cationic dispersing agents, cationic dispersing agents having a phenyl group, for example, benzene konium chloride (BKC), sodium dodecylbenzene sulfonate (NaDDBS), and triton-X are preferably used. The amount of cationic dispersing agent in the nickel plating solution 60 is preferably about 100˜200 wt % of the amount of the CNTs. If the amount of cationic dispersing agent is significantly smaller, the CNTs are not sufficiently prevented from being agglomerated, whereas if the amount of cationic dispersing agent is excessive, the cationic dispersing agents are attached to the electrode, lowering a plating speed of the CNT-nickel composite material.

FIG. 9 is a schematic diagram illustrating the CNTs 30 coupled to a cationic dispersing agent 40. The cationic dispersing agent 40 having the phenyl group is coupled with the CNTs 30, and prevents the CNTs 30 from being agglomerated in the plating solution 60. A dispersion degree of the CNTs may be increased through supersonic treatment to the plating solution. After dispersing the CNTs in the nickel plating solution, agglomerated CNTs can be filtrated through a filter.

With the plating solution 60 contained in a plating bath 21, the aluminum substrate 101 having the porous AAO layer 102 formed thereon is dipped into the plating solution 60. With the aluminum substrate 101 connected to a DC power source 25, CNT-nickel composite plating is performed by applying the predetermined voltage to the aluminum substrate 101. At this time, the CNT-nickel composite material is embedded the predetermined depth into the pores 103 by controlling the plating time. As a result, the resultant as shown in FIG. 5 is formed. Referring to FIG. 5, the CNT-nickel composite material 104 comprising the CNTs 30 is embedded the predetermined depth into the pores 103. In the present embodiment, the CNT-nickel composite material 104 may be formed to a thickness or length of about 0.1˜0.2 μm in each of the pores 103.

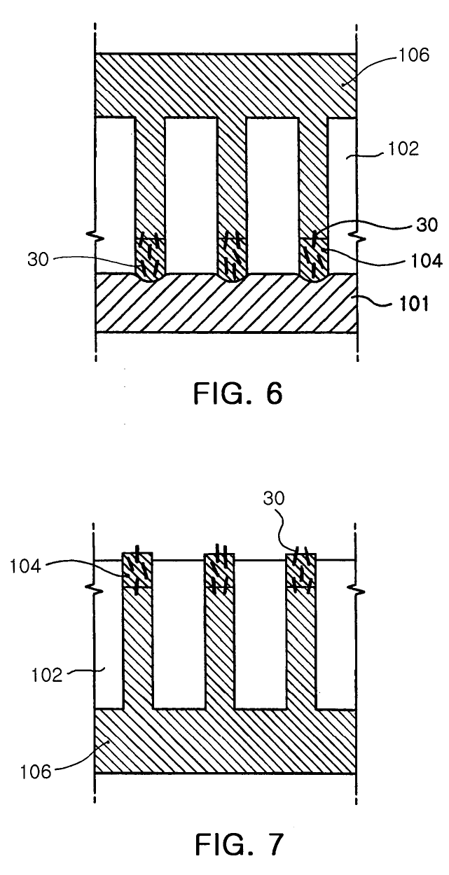

Next, referring to FIG. 6, nickel electro-plating is performed on the resultant comprising the CNT-nickel composite material 104, thereby forming the nickel layer 106 on the AAO layer 102. At this time, the nickel layer 106 completely fills the pores 103, and is thickly formed to a predetermined thickness on an upper surface of the AAO layer 102. For example, the nickel layer 106 may have a thickness of about 50˜100 μm on the upper surface of the AAO layer 102. Since the nickel layer 106 acts as a substrate for the field emitter array, it is desirable that the nickel layer 106 be formed to a sufficient thickness.

Then, as shown in FIG. 7, wet-etching is performed using a nitric acid solution to completely remove the aluminum substrate 101. At this time, since the CNT-nickel composite material 104 is also partially etched by the nitric acid solution, at least one CNT 30 can be exposed from the upper surface of the CNT-nickel composite material 104.

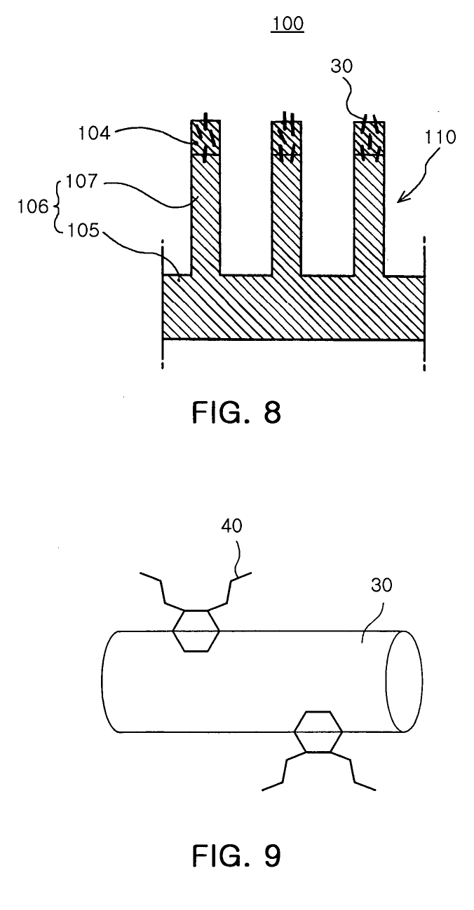

Next, as shown in FIG. 8, the field emitter array 100 of the invention is provided by completely removing the AAO layer 102 through by wet etching using the phosphoric acid solution. For example, the AAO layer 102 can be completely removed by dipping the resultant as shown in FIG. 7 into 0.5M phosphoric acid solution. In this manner, when the AAO layer 102 is completely removed, the nickel layer 106 can be completely exposed. Accordingly, as shown in FIG. 8, the nano-pillars 110, each comprising the upper portion 104 formed of the CNT-nickel composite material, and the nano-pillar body 107 formed of nickel, is provided. The nickel layer 106 may be divided into the nickel substrate 105 acting as the substrate, and the nano-pillar bodies 107 integrated to the nickel substrate 105 while extending perpendicular thereto. The CNTs 30 are exposed from the upper surface of the upper portions 104 on the nano-pillar bodies 107. The exposed CNTs 30 act as the emitter for the field emitter array.

According to the method for manufacturing the field emitter array, the distribution density of the nano-pillars 110 can be easily controlled by adjusting the density of the pores of the AAO layer 102. Accordingly, the distribution density of the CNT emitters 30 on the upper portions 104 can be easily controlled.

As apparent from the above description, according to the invention, since the CNTs are provided on the upper surface of the nano-pillars, the field emission efficiency can be further enhanced. Additionally, since the substrate, and the nano-pillars extending perpendicular to the substrate are integrated, and formed of the same material, field emission efficiency can be prevented from being lowered due to contact resistance. According to the method of the invention, the distribution density of CNT emitters can be easily controlled by adjusting the distribution density of pores in the AAO layer. Moreover, since the field emitter array is manufactured using the liquid-phase plating process as described above, the uniformity of the CNTs can be enhanced, thereby realizing a large area field emitter array at lower cost. Furthermore, since the CNT emitters are steadily embedded in nickel, the attachment strength of the CNT emitters can also be reinforced. Additionally, the field emitter array is manufactured using the CTNs and nickel without the binder, the field emitter of the invention does not suffer form conventional out-gassing phenomena while ensuring a remarkably extended life span.

It should be understood that the embodiments and the accompanying drawings have been described for illustrative purposes and the present invention is limited only by the following claims. Further, those skilled in the art will appreciate that various modifications, additions and substitutions are allowed without departing from the scope and spirit of the invention as set forth in the accompanying claims.

What is claimed is:

1. A field emitter array, including:
a nickel substrate; and
a plurality of nano-pillars extending perpendicular to the nickel substrate,
wherein each of the nano-pillars comprises a nickel nano-pillar body integrated to the nickel substrate and extending perpendicular to the nickel substrate, and an upper portion of the nano-pillar formed on the nano-pillar body and comprising a CNT-nickel composite material, wherein at least one CNT is exposed from an upper surface of the nano-pillars.

2. The field emitter array as set forth in claim 1, wherein the at least one CNT is exposed only from an upper surface of the upper portion of the nano-pillar.

3. The field emitter array as set forth in claim 1, wherein each of the nano-pillars has a length of 2˜5 μm, and a diameter of 100˜400 nM.

4. The field emitter array as set forth in claim 1, wherein the upper portion of the nano-pillar has a length of 0.1˜0.2 μm.

5. The field emitter array as set forth in claim 1, wherein the nickel substrate has a thickness of 50˜100 μm.

6. A method for manufacturing a field emitter array, comprising the steps of:
preparing an aluminum substrate having an anodized alumina layer formed thereon, the anodized alumina layer having a plurality of pores uniformly distributed thereon;
performing CNT-nickel composite plating using a nickel plating solution having CNTs dispersed therein such that a CNT-nickel composite material is embedded a predetermined depth into the pores;
forming a nickel layer so as to completely fill the pores and to have a predetermined thickness on the anodized alumina layer; and
forming a plurality of nano-pillars, each having at least one CNT exposed from an upper surface thereof, by removing the aluminum substrate and the anodized alumina layer.

7. The method as set forth in claim 6, wherein the nickel plating solution having the CNTs dispersed therein comprises a cationic dispersing agent.

8. The method as set forth in claim 7, wherein the cationic dispersing agent is at least one selected from the group consisting of benzene konium chloride, sodium dodecylbenzene sulfonate, and triton-X.

9. The method as set forth in claim 7, wherein the content of the dispersing agent in the nickel plating solution having the CNTs dispersed therein is about 100˜200 wt % of the amount of the CNTs.

10. The method as set forth in claim 6, wherein the step of forming the nickel layer so as to completely fill the pores is performed by electroplating.

11. The method as set forth in claim 6, wherein the step of forming the plurality of nano-pillars comprises wet etching the aluminum substrate, and wet etching the anodized alumina layer.

12. The method as set forth in claim 11, wherein, when wet etching the aluminum substrate, the at least one CNT is protruded by etching a portion of a metallic material in the CNT-nickel composite material.

13. The method as set forth in claim 11, wherein wet etching of the aluminum substrate is performed using a nitric acid solution.

14. The method as set forth in claim 11, wherein etching of the anodized alumina layer is performed using a phosphoric acid solution.

15. The method as set forth in claim 6, wherein each of the pores has a total depth of 2˜5 μm, and a diameter of 100˜400 nm.

16. The method as set forth in claim 6, wherein the CNT-nickel composite material is formed to a thickness of about 0.1˜0.2 μm in each of the pores.

17. The method as set forth in claim 6, wherein the nickel layer has a thickness of 50˜100 μm on the anodized alumina layer.
